(19) United States
(12) Patent Application Publication
(10) Pub. No.: US 2015/0325810 A1
(43) Pub. Date: Nov. 12, 2015

(54) ORGANIC EL LAMINATE

(71) Applicant: FUJIFILM Corporation, Tokyo (JP)

(72) Inventor: Eijiro IWASE, Ashigarakami-gun (JP)

(73) Assignee: FUJIFILM CORPORATION, Tokyo (JP)

(21) Appl. No.: 14/801,064

(22) Filed: Jul. 16, 2015

Related U.S. Application Data
(63) Continuation of application No. PCT/JP2014/054524, filed on Feb. 25, 2014.

(30) Foreign Application Priority Data
Mar. 8, 2013 (JP) 2013-046533

(51) Int. Cl. H01L 51/52; H01L 51/50

(52) U.S. Cl. CPC H01L 51/5253; H01L 51/5012; H01L 51/524; H01L 2251/303; H01L 2251/5315; H01L 2251/558

(57) ABSTRACT

In the organic EL laminate, a gas barrier film, which has a laminated structure composed of an organic film and an inorganic film, adheres to a passivation film, which covers a light emitting element using an organic EL material, by an adhesive in a state in which the inorganic film faces the passivation film and the inorganic film and the passivation film are formed of the same material.

### CROSS-REFERENCE TO RELATED APPLICATIONS

This application is a Continuation of PCT International Application No. PCT/JP2014/54524, filed on Feb. 25, 2014, which claims priority under 35 U.S.C. §119(a) to Japanese Patent Application No. 2013-046533, filed on Mar. 8, 2013. Each of the above application(s) is hereby expressly incorporated by reference, in its entirety, into the present application.

### BACKGROUND OF THE INVENTION

1. Field of the Invention

The present invention relates to an organic EL laminate obtained by sealing an organic EL device, in which a light emitting element is protected with a passivation film, with a sealing substrate (gas barrier film).

2. Description of the Related Art

An organic EL device (OLED device) using an organic electro luminescence (EL) material is used in displays, illumination devices, and the like.

The organic EL material used in the organic EL device is extremely vulnerable to moisture. Therefore, for the organic EL device, a structure in which the peripheral portion thereof is sealed with a glass plate or a metal plate is adopted to prevent deterioration of the organic EL material due to moisture.

However, in such a method, because the entirety of the device is sealed with a metal or glass, the organic EL device becomes heavy and thick. Furthermore, with such a method, it is difficult to follow the recent trend that requires the organic EL device to be more flexible.

In order to solve the above problems, as disclosed in JP2010-198926A and JP5036628B, a method has been developed which is for lightening and thinning down an organic EL device by giving gas barrier properties to a light emitting element (organic EL element) using an organic EL material.

Specifically, by adopting a laminate structure (organic EL laminate) obtained by covering a light emitting element, which has an organic EL material, an electrode, and the like on an element substrate, with a passivation film (protective film) having gas barrier properties and attaching a sealing substrate onto the passivation film by using an adhesive, deterioration of the organic EL element due to moisture is prevented.

According to the aforementioned documents, examples of materials forming the passivation film in such an organic EL laminate include inorganic materials such as silicon nitride, silicon oxide, and silicon oxynitride that exhibit gas barrier properties.

Furthermore, according to the aforementioned documents, examples of materials forming the sealing substrate include glass, plastic, quartz, resins, metals, and the like.

### SUMMARY OF THE INVENTION

If the constitution using the passivation film and the sealing substrate is adopted, the periphery of the organic EL device does not need to be sealed with a metal plate or a glass plate, and therefore the organic EL device can be lightened and thinned down.

In order to further lighten and thin down the device in a better way, it is more advantageous to use a plastic film than to use glass or the like as the sealing substrate.

Through examination, the present inventor found that if the organic EL device, in which a light emitting element is covered with a passivation film, is sealed with a plastic film as a sealing substrate, the organic EL device can be lightened and thinned down. However, interlayer peeling, deterioration of the light emitting element caused by the plastic film, and the like occur in some cases.

An object of the present invention is to solve the aforementioned problems of the related art, and to provide an organic EL laminate that is obtained by sealing an organic EL device, in which a light emitting element using an organic EL material is covered with a passivation film, with a sealing substrate, can prevent interlayer peeling, and can more preferably prevent deterioration of the light emitting element due to moisture or the like.

In order to achieve the aforementioned object, the present invention provides an organic EL laminate including an organic EL device having a light emitting element using an organic EL material and a passivation film covering the light emitting element, and a gas barrier film sealing the organic EL device, in which the organic EL device and the gas barrier film adhere to each other by an adhesive, the gas barrier film has a support and at least one or more combinations, each of which is composed of an inorganic film and an organic film that becomes an underlayer of the inorganic film, on the support, a surface layer of the gas barrier film is an inorganic film, the passivation film and the surface layer of the gas barrier film are formed of the same material, and the passivation film and the surface layer of the gas barrier film face each other.

In the organic EL laminate of the present invention, a thickness of the adhesive is preferably greater than 1 μm and equal to or less than 100 μm.

The adhesive preferably contains a silane coupling agent, each of the passivation film and the surface layer of the gas barrier film is preferably a film of a silicon compound, and at least either an —O group or a —OH group is preferably introduced into a surface of the film of a silicon compound.

Each of the passivation film and the inorganic film as the surface layer of the gas barrier film is preferably a film of silicon nitride.

A retardation of the support is preferably equal to or less than 300 nm.

A water vapor transmission rate of the support is preferably equal to or less than 300 [g/(m²·day)].

A water vapor transmission rate of the gas barrier film is preferably less than 1×10⁻⁴ [g/(m²·day)].

A thickness of the passivation film is preferably equal to or less than 5 μm.

A thickness of the organic film is preferably 0.5 μm to 5 μm.

The organic EL device is preferably a top emission type.

The organic EL laminate preferably has a plurality of inorganic films, and all of the inorganic films are preferably formed of the same material.

According to the present invention, in an organic EL laminate obtained by sealing an organic EL device, in which a light emitting element is covered with a passivation film, with a sealing substrate, a gas barrier film of which the surface layer is composed of an inorganic film having gas barrier properties is used as the sealing substrate. As a result, it is possible to lighten and thin down the organic EL laminate, prevent interlayer peeling that occurs in the organic EL laminate, and more preferably prevent deterioration of the light emitting element due to moisture or the like.

### BRIEF DESCRIPTION OF THE DRAWINGS

FIG. 1 is a view schematically showing an example of an organic EL laminate of the present invention.

FIGS. 2A and 2B each is schematically view showing another example of a gas barrier film used in the organic EL laminate of the present invention.

### DESCRIPTION OF THE PREFERRED EMBODIMENTS

Hereinafter, the organic EL laminate of the present invention will be specifically described based on preferable examples described in the attached drawings.

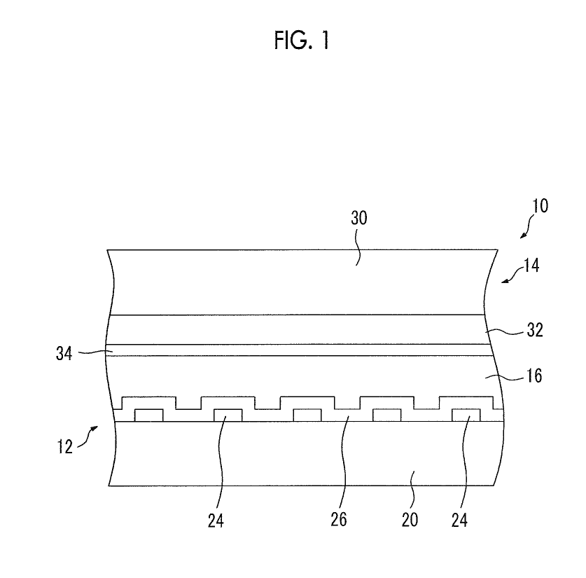

FIG. 1 schematically shows an example of the organic EL laminate of the present invention.

As shown in FIG. 1, in an organic EL laminate 10, an organic EL device 12, in which a light emitting element 24 using an organic EL material is formed, and a gas barrier film 14 adhere to each other by an adhesive (an adhesive layer or an adhesion layer) 16.

In the organic EL device 12, the light emitting element 24 is formed on an element substrate 20 and covered with a passivation film 26.

As the organic EL device 12, it is possible to use known organic EL devices (OLED devices) that are used in various organic EL devices such as organic EL displays and organic EL illumination devices, as long as the organic EL devices have the light emitting element 24 using an organic EL material and the passivation film 26 covering the light emitting element 24 for protecting the light emitting element 24 from moisture, oxygen gas, or the like.

As the element substrate 20, it is possible to use element substrates used in various organic EL devices. Examples of materials of the element substrate 20 include glass, plastic, metals, ceramic, and the like.

It is preferable that the organic EL laminate 10 can prevent moisture or the like from passing through the element substrate 20 and reaching the light emitting element 24 so as to prevent the deterioration of the light emitting element 24 due to moisture or the like. Therefore, as the element substrate 20, it is preferable to use a substrate composed of a material such as glass or a metal in which the content and transmission rate of moisture or the like are small.

The organic EL laminate 10 includes, as a sealing substrate sealing the organic EL device 12, the gas barrier film 14 having an organic layer/inorganic layer laminated structure in which an organic film 32 and an inorganic film 34 are laminated on each other. The organic EL laminate 10 is preferably used in a top emission-type organic EL device that emits light from opposite side (the side of the gas barrier film 14) of the element substrate 20.

When the organic EL device 12 is the top emission type, the element substrate 20 does not need to have light transmittance. Accordingly, when the organic EL laminate 10 is used in the top emission-type organic EL device, as the element substrate 20, a flexible metal film (metal plate) having an insulating layer may be used such as aluminum foil having an anodic oxide film on a surface (lower side in FIG. 1) thereof or a laminate of aluminum foil and polyimide.

In the organic EL laminate 10, the gas barrier film 14 is used as a sealing substrate. Therefore, if the flexible metal film having an insulating layer is used as the element substrate 20, it is possible to preferably prepare a flexible organic EL display, a flexible organic EL illumination device, and the like.

As described above, in the organic EL laminate 10, a known organic EL device can be used as the organic EL device 12.

As the light emitting element (organic EL element) 24 formed on the element substrate 20, it is possible to use known light emitting elements which have a light emitting unit (light emitting layer) formed of an organic EL material, an electrode, a hole injection layer, a hole transport layer, an electron transport layer, an electron injection layer, and the like and use an organic EL material.

The light emitting element 24 can be formed by a known method according to the constitution, use, size, and the like of the organic EL laminate 10.

The organic EL device 12 has the passivation film (protective film) 26 covering the light emitting element 24 (or additionally covering the surface of the element substrate 20).

The passivation film 26 prevents deterioration of the light emitting element 24 (particularly, the organic EL material) by inhibiting moisture, oxygen, or the like from reaching the light emitting element 24.

As the passivation film 26, it is possible to use various films (layers) which are used in known organic EL devices and formed of a material that exhibits gas barrier properties.

Examples of the passivation film 26 include films formed of an inorganic compound having gas barrier properties. Among these, films formed of a silicon compound such as silicon nitride, silicon oxide, or silicon oxynitride are preferable. Particularly, in view of a high degree of gas barrier properties, optical characteristics obtained when the passivation film 26 is used in a top emission-type organic EL device, and the like, a film formed of silicon nitride is more preferable as the passivation film 26.

The passivation film 26 can be formed by a known method according to the material forming the film.

In the present embodiment, the passivation film 26 is formed of the same material as the inorganic film 34 as the surface layer of the gas barrier film 14.

It is preferable that the passivation film 26 is formed of a silicon compound, and either or both of an —O group and a —OH group are introduced into the surface (the surface on the side of the gas barrier film 14) thereof. It is more preferable that a —OH group is introduced into the surface thereof. Especially, it is preferable that the passivation film 26 is formed of silicon nitride, and either or both of an —O group and a —OH group are introduced into the surface thereof. It is more preferable that a —OH group is introduced into the surface thereof.

If an —O group or a —OH group is introduced into the surface of the passivation film 26, and an adhesive 16 contains a silane coupling agent, excellent adhesiveness between the organic EL device 12 (passivation film 26) and the adhesive 16 can be obtained. This point will be specifically described later.

Generally, the passivation film 26 formed of a silicon compound is formed by performing a vapor-phase deposition method (vapor-phase film deposition method) such as plasma CVD or sputtering in a state of keeping the temperature at which the light emitting element 24 is not damaged.

In a film formed of a silicon compound by a vapor-phase deposition method at a low temperature, not all the silicon atoms in the film form a target compound such as silicon nitride, and there are silicon atoms having direct bonds that have not participated in bonding. Particularly, the surface of the film has a large amount of silicon atoms having direct bonds that have not participated in bonding. Accordingly, if the surface of the film is exposed to the air (atmosphere) after the passivation film 26 is formed, an —O group or a —OH group is bonded to the direct bonds that have not participated in bonding. As a result, an —O group or a —OH group (particularly a —OH group) is introduced into the surface of the passivation film 26.

A thickness of the passivation film 26 may be appropriately set according to the use, size, and the like of the organic EL laminate 10.

Generally, as the thickness of the passivation film 26 increases, the light emitting element 24 is protected better from moisture or the like by the passivation film 26.

However, in the organic EL device 12, it is difficult to form the passivation film 26 at a high temperature so as to prevent damage of the light emitting element 24. Therefore, it takes time and trouble to form a thick passivation film 26, and thus the cost increases. Furthermore, because the passivation film 26 is a film formed of an inorganic material, if it is too thick, the film is damaged by cracks or the like that naturally occurs due to the internal stress thereof.

In the organic EL laminate 10, the high-performance gas barrier film 14 having the organic layer/inorganic layer laminated structure is used as a sealing substrate by causing the inorganic film 34 to face the side of the passivation film 26. Accordingly, even if the passivation film 26 is thinned down, deterioration of the light emitting element 24 due to moisture or the like can be sufficiently prevented.

The thickness of the passivation film 26 is preferably equal to or less than 5 μm, more preferably equal to or less than 2 μm, and particularly preferably equal to or less than 1.5 μm. If the thickness is within the above range, the organic EL laminate 10 can be made into a thin and flexible film in a more preferable way, and the cost can be reduced.

The gas barrier film 14 has a support 30 and one or more combinations on the support 30, each of the combinations being composed of the inorganic film 34 and the organic film 32. It is preferable that the gas barrier film 14 has the organic film 32 on the support 30 and has the inorganic film 34 on the organic film 32. That is, in the gas barrier film 14, the support 30, the organic film 32, and the inorganic film 34 are laminated on each other in this order.

The organic EL laminate 10 has a constitution in which the organic EL device 12 and the gas barrier film 14 adhere to each other by using the adhesive 16 in a state in which the passivation film 26 and the inorganic film 34 face each other.

In the organic EL laminate 10, the gas barrier film 14 has one or more combinations on the support 30, each of the combinations being composed of the inorganic film 34 and the organic film 32 that is an underlayer of the inorganic film 34. Furthermore, the surface (surface on the opposite side of the support 30) of the gas barrier film 14 is the inorganic film 34.

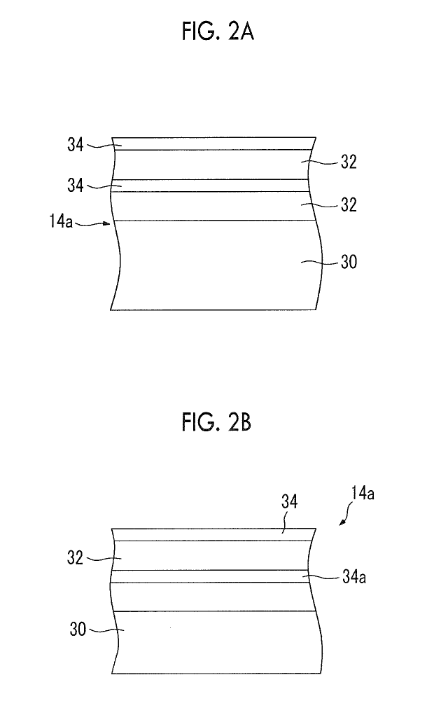

For example, the gas barrier film 14 may have two combinations, each of which is composed of the inorganic film 34 and the organic film 32 as an underlayer, just like a gas barrier film 14a shown in FIG. 2A. Alternatively, the gas barrier film 14 may be three or more combinations described above.

As the support 30 of the gas barrier film 14, it is preferable to use a low retardation film having a value of retardation of equal to or less than 300 nm. The value of retardation of the support 30 is more preferably equal to or less than 150 nm, even more preferably equal to or less than 10 nm, and particularly preferably equal to or less than 5 nm. The value of retardation of the support 30 is represented by the product of a birefringence of the film and a thickness (nm) of the film. For example, the organic film 32 is formed by a so-called coating method.

Many of the low retardation films having a small value of retardation are easily dissolved in a solvent. Therefore, if the low retardation film is used as the support 30, and the organic film 32 is formed on the surface thereof by the coating method, in some cases, the support 30 is dissolved in an organic solvent contained in the coating, and thus optical characteristics of the support undergo deterioration such as change in retardation.

If the support 30 is likely to be dissolved at the time of forming the organic film 32, just like a gas barrier film 14b shown in FIG. 2B, a protective inorganic film 34a for protecting the support 30 may be formed on the surface of the support 30, and one or more combinations, each of which is composed of the organic film 32 and the inorganic film 34, may be formed on the protective inorganic film 34a. The same film as the inorganic film 34 can be used as the protective inorganic film 34a.

When the protective inorganic film 34a is formed on the surface of the support 30, the gas barrier film 14 may have a mixed layer formed as a result of mixing of components of the support 30 and the protective inorganic film 34a, between the support 30 and the protective inorganic film 34a. If the gas barrier film 14 has the mixed layer, it is possible to more effectively prevent the gas barrier film 14b (particularly, the inorganic film 34) from being damaged due to the change in temperature or humidity. At the time of forming the protective inorganic film 34a by a vapor-phase deposition method, by controlling etching of the support 30 caused by plasma or controlling attraction of ions or the like caused by bias applied to the support 30, the mixed layer can be formed.

As the support 30 of the gas barrier film 14, those used as a support in known gas barrier films can be used.

Especially, films formed of various plastics (polymer materials/resin materials) are preferably used, because they make it easy to thin down or lighten the organic EL laminate 10 and are preferable for making the organic EL laminate 10 flexible.

Preferable examples of materials of the support 30 include plastic films formed of any of polyethylene terephthalate (PET), polyethylene naphthalate (PEN), polyethylene, polypropylene, polystyrene, polyamide, polyvinyl chloride, polycarbonate, polyacrylonitrile, polyimide, transparent polyimide, polyacrylate, polymethacrylate, a cycloolefin polymer (alicyclic polyolefin, COP), a cycloolefin copolymer (COC), and triacetyl cellulose (TAC).

The organic EL laminate 10 is preferably used in a top emission-type organic EL device. Considering the optical characteristics of the organic EL laminate 10, as the support 30, a low retardation film having a value of retardation of less than 300 nm is preferably used, a low retardation film having a value of retardation of equal to or less than 200 nm is more preferably used, and a low retardation film having a value of retardation of equal to or less than 150 nm is particularly preferably used.

In order to reduce a load of the passivation film 26 and the inorganic film 34 which will be described later, and to more preferably prevent deterioration of the light emitting element 24 due to moisture or the like, the support 30 preferably has a low water vapor transmission rate and contains a small amount of water. The water vapor transmission rate of the support 30 is preferably equal to or less than 300 [g/(m²·day)], and more preferably equal to or less than 200 [g/(m²·day)].

Considering the aforementioned points, as the support 30, for example, a plastic film formed of any of polycarbonate, a cycloolefin polymer, a cycloolefin copolymer, triacetyl cellulose, and transparent polyimide is preferable. As the support 30, a plastic film formed of any of polycarbonate, a cycloolefin polymer, and a cycloolefin copolymer is more preferable, and a plastic film formed of a cycloolefin copolymer is even more preferable.

A thickness of the support 30 may be appropriately set according to the use or size of the organic EL laminate 10. The thickness of the support 30 is preferably about 10 μm to 200 μm. If the thickness of the support 30 is within the above range, in view of lightening and thinning down the organic EL laminate 10, preferable results are obtained.

In view of lightening and thinning down the organic EL laminate 10, the total thickness of the support 30 and the adhesive 16 is preferably smaller than 300 μm which is a thickness of thin glass.

The support 30 may be obtained by forming a film, which performs a required function, such as an antireflection film on the surface of a plastic film.

The organic film 32 is formed on the support 30. The organic film 32 is a film formed of an organic compound (film (layer) containing an organic compound as a main component). Basically, the organic film 32 is formed by crosslinking (polymerizing) a monomer and/or an oligomer.

In the gas barrier film 14, the organic film 32 becomes an underlayer of the inorganic film 34 that mainly exhibits gas barrier properties.

The organic film 32 that becomes the underlayer of the inorganic film 34 functions as a cushion for the inorganic film 34. Consequently, when the organic EL device 12 and the gas barrier film 14 are pressed together so as to adhere to each other, or when the organic EL laminate 10 (organic EL device) receives external impact, due to the cushioning effect of the organic film 32, damage of the inorganic film 34 can be prevented.

As a result, in the organic EL laminate 10, the gas barrier film 14 demonstrates appropriate gas barrier performance, and therefore deterioration of the light emitting element 24 due to moisture can be preferably prevented.

If the gas barrier film 14 has the organic film 32, irregularities on the surface of the support 30, foreign substances having adhered to the surface, and the like can be embedded in (covered with) the organic film 32, and thus a surface for forming the inorganic film 34 (a film formation surface) can be appropriately prepared. If the organic film 32 is formed, the surface for forming the inorganic film 34 becomes in a state appropriate for forming a film. Consequently, on the entire surface for forming the film, an appropriate inorganic film 34 free of cracks, fissures, or the like can be formed without a void.

If the gas barrier film 14 has the organic layer/inorganic layer laminated structure, a high degree of gas barrier performance can be obtained in which the water vapor transmission rate is less than 1×10⁻⁴ [g/(m²·day)]. That is, in the organic EL laminate 10, if the gas barrier film 14, which has the organic layer/inorganic layer laminated structure and demonstrates a high degree of gas barrier performance, is used as a sealing substrate, even if the passivation film 26 is a thin layer having a thickness of equal to or less than 2 μm, it is possible to more effectively prevent the deterioration of the light emitting element 24 due to moisture or the like.

Various organic compounds (resins/polymer compounds) can be used as materials forming the organic film 32.

Preferable examples of materials of the organic film 32 include thermoplastic resins such as polyester, an acryl resin, a methacryl resin, a methacrylic acid-maleic acid copolymer, polystyrene, a transparent fluorine resin, polyimide, fluorinated polyimide, polyamide, polyamide imide, polyether imide, cellulose acylate, polyurethane, polyether ether ketone, polycarbonate, alicyclic polyolefin, polyarylate, polyether sulfone, polysulfone, fluorene ring-modified polycarbonate, alicyclic-modified polycarbonate, fluorene ring-modified polyester, and an acryloyl compound, polysiloxane, and other organic silicon compounds. A plurality of these materials may be concurrently used.

Among these, as the material of the organic film 32, either or both of a radically polymerizable compound and a cationically polymerizable compound having an ether group as a functional group are preferable, because these compounds are excellent in terms of a glass transition temperature, strength, and the like.

Particularly, as the material of the organic film 32, an acryl resin or a methacryl resin is more preferable which contains, as a main component, a polymer of a monomer or an oligomer of acrylate and/or methacrylate and has a glass transition temperature of equal to or higher than 120° C., because such a resin has a low refractive index and a high degree of transparency and is excellent in terms of optical characteristics in addition to the strength.

Especially, as the material of the organic film 32, an acryl resin or a methacryl resin is even more preferable which contains, as a main component, a polymer of a monomer or an oligomer of acrylate and/or methacrylate having two or more functional groups, particularly, three or more functional groups, such as dipropylene glycol di(meth)acrylate (DPGDA), trimethylolpropane tri(meth)acrylate (TMPTA), and dipentaerythritol hexa(meth)acrylate (DPHA). Furthermore, as the material of the organic film 32, a plurality of the acryl resins or methacryl resins is preferably used.

If the organic film 32 is formed of the aforementioned acryl resin or methacryl resin, the inorganic film 34 can be formed on the underlayer having a stable skeleton, and therefore a denser inorganic film 34 having a high degree of gas barrier properties is formed.

A thickness of the organic film 32 is preferably 0.5 μm to 5 μm, and more preferably 1 μm to 3 μm.

If the thickness of the organic film 32 is equal to or greater than 0.5 μm, when the organic EL device 12 and the gas barrier film 14 are pressed together so as to adhere to each other, the organic film 32 exerts a sufficient effect as a cushion, and accordingly, damage of the inorganic film 34 can be more reliably prevented. Moreover, if the thickness of the organic film 32 is equal to or greater than 0.5 μm, the surface for forming the inorganic film 34 can be more preferably prepared. Consequently, the inorganic film 34 free of cracks, fissures, or the like is formed in a wider range of the surface for forming the film.

In addition, if the thickness of the organic film 32 is equal to or less than 5 μm, it is possible to preferably prevent the problem in that the organic film 32 cracks or the gas barrier film 14 is curled due to the excessive thickness of the organic film 32.

It is preferable that the organic film 32 has a high degree of surface smoothness, because such an organic film 32 can prevent the damage of the inorganic film 34 by more preferably functioning as a cushion, and the surface for forming the inorganic film 34 can be more appropriately prepared.

Specifically, an average surface roughness Ra of the organic film 32 is preferably equal to or less than 10 nm, and more preferably equal to or less than 5 μm.

When the gas barrier film has a plurality of organic films 32 just like the gas barrier film 14a shown in FIG. 2A, the thicknesses of the organic films 32 may be the same as or different from each other.

When the gas barrier film has a plurality of organic films 32, the materials forming the organic films 32 may be the same as or different from each other. In view of productivity and the like, it is preferable that all of the organic films 32 are formed of the same material.

The organic film 32 can be formed by a known method such as a coating method or a flash vapor deposition method.

In order to improve the adhesiveness between the organic film 32 and the inorganic film 34 or the protective inorganic film 34a, it is preferable that the organic film 32 contains a silane coupling agent.

The inorganic film 34 is formed on the organic film 32 which functions as an underlayer of the inorganic film 34.

The inorganic film 34 is a film formed of an inorganic compound (film (layer) containing an inorganic compound as a main component), and mainly exhibits gas barrier properties in the gas barrier film 14.

In the organic EL laminate 10, the surface layer (film on a surface opposite to the support 30) of the gas barrier film 14 is the inorganic film 34.

As the inorganic film 34, a film formed of an inorganic compound that exhibits gas barrier properties is used.

Preferable examples of materials of the inorganic film 34 include films composed of inorganic compounds like metal oxides such as aluminum oxide, magnesium oxide, tantalum oxide, zirconium oxide, titanium oxide, and indium tin oxide (ITO); metal nitrides such as aluminum nitride; metal carbides such as aluminum carbide; oxides of silicon such as silicon oxide, silicon oxynitride, silicon oxycarbide, and silicon oxynitrocarbide; nitrides of silicon such as silicon nitride and silicon nitrocarbide; carbides of silicon such as silicon carbide; hydrides of these; a mixture of two or more kinds of these; and the above compounds containing hydrogen.

Particularly, as the inorganic film 34, for example, a film formed of a silicon compound is preferable, because such a film has a high degree of transparency and can exhibit excellent gas barrier properties. Especially, as the inorganic film 34, for example, a film formed of silicon nitride is more preferable, because such a film exhibits better gas barrier properties and has a high degree of transparency.

The inorganic film 34 as the surface layer of the gas barrier film 14 and the passivation film 26 are formed of the same material.

When the gas barrier film contains a plurality of inorganic films 34 (including the protective inorganic film 34a) just like the gas barrier film 14a and the gas barrier film 14b shown in FIGS. 2A and 2B, at least the inorganic film 34 as the surface layer thereof may be formed of the same material as the passivation film 26. That is, when the gas barrier film has a plurality of inorganic films 34, the materials forming the inorganic films 34 may be different from each other. Considering productivity and the like, it is preferable that all of the inorganic films 34 are formed of the same material.

When the inorganic film 34 is formed of a silicon compound, either or both of an —O group and a —OH group are preferably introduced into the surface of the inorganic film 34 as the surface layer, and a —OH group is more preferably introduced into the surface of the inorganic film 34. Particularly, it is preferable that the inorganic film 34 as the surface layer is formed of silicon nitride, and either or both of an —O group and a —OH group are introduced into the surface thereof. It is more preferable that a —OH group is introduced into the surface thereof.

If an —O group or a —OH group is introduced into the surface of the inorganic film 34 as the surface layer, and the adhesive 16 contains a silane coupling agent, preferable adhesiveness between the gas barrier film 14 (inorganic film 34) and the adhesive 16 can be secured. This point will be specifically described later.

A thickness of the inorganic film 34 may be appropriately determined according to the material forming the inorganic film 34, such that intended gas barrier properties can be exhibited.

The thickness of the inorganic film 34 is preferably 10 nm to 200 nm, more preferably 10 nm to 100 nm, and even more preferably 15 nm to 75 nm.

If the thickness of the inorganic film 34 is equal to or greater than 10 nm, sufficient gas barrier performance is stably demonstrated. Generally, the inorganic film 34 is brittle. Accordingly, if it is too thick, cracks, fissures, peeling, and the like are likely to occur in the inorganic film 34. Therefore, if the thickness of the inorganic film 34 is equal to or less than 200 nm, it is possible to prevent the occurrence of cracks.

As in examples shown in FIGS. 2A and 2B, if the gas barrier film has a plurality of inorganic films 34 (including the protective inorganic film 34a), the thicknesses of the inorganic films 34 may be the same as or different from each other.

For example, the inorganic film 34 can be formed by a known method. Preferable examples of the method for forming the inorganic film 34 include vapor-phase deposition methods like plasma CVD such as CCP-CVD or ICP-CVD, sputtering such as magnetron sputtering or reactive sputtering, and vacuum vapor deposition.

Similarly to the passivation film 26, if the inorganic film 34 is formed by a vapor-phase deposition method, and then a surface of the film is exposed to the air, an —O group or a —OH group (particularly, a —OH group) can be introduced into the surface of the inorganic film 34.

The organic EL laminate 10 has a constitution in which the organic EL device 12, which has the passivation film 26 covering the light emitting element 24 (or additionally covering the surface of the element substrate 20), and the gas barrier film 14 which has an organic layer/inorganic layer laminated structure and includes the inorganic film 34 as the surface layer thereof adhere to each other by the adhesive 16 in a state in which the passivation film 26 and the inorganic film 34 face each other.

Furthermore, in the organic EL laminate 10, the passivation film 26 and the inorganic film 34 as the surface layer of the gas barrier film 14 are formed of the same material. In the following description, unless otherwise specified, the “inorganic film 34” indicates the “inorganic film 34 as the surface layer”.

As the organic EL device (particularly, a top emission-type organic EL device) 12, a constitution is known in which the passivation film 26 is formed by covering the light emitting element 24 formed on the element substrate 20, and the surface of the passivation film 26 is sealed with a sealing substrate by using an adhesive.

In JP2010-198926A and JP5036628B, various substances such as a glass plate and a plastic film are exemplified as the sealing substrate of the organic EL device 12, and generally, a glass plate is used as the sealing substrate.

However, in recent years, it has been increasingly required for organic EL devices to be lightened and thinned down. In addition, depending on the use thereof, it has been required for organic EL devices to have flexibility such that they can be folded or bent.

Considering the request to lightening and thinning down of the organic EL devices, it is advantageous to use a plastic film as the sealing substrate sealing the organic EL device 12.

However, through examination, the present inventor found that if a plastic film is used as the sealing substrate, it is difficult to make the adhesive to exhibit sufficient adhesiveness with respect to both the passivation film 26 (particularly, a passivation film formed of a silicon compound) and the sealing substrate.

Interlayer peeling occurs between the passivation film 26 and the adhesive and/or between the adhesive and the plastic film as the sealant, and as a result, gas such as moisture remains in the interfacial portion thereof in the form of air bubbles. Consequently, even when the organic EL laminate 10 has the passivation film, moisture or the like reaches the light emitting element 24 over a long period of time, and thus the light emitting element 24 deteriorates.

Furthermore, as a result of examination, the present inventor found that the gas (so-called outgas) such as moisture released from the plastic film also causes the deterioration of adhesiveness.

Various gases such as moisture are contained in the plastic film, and the gases (so-called outgas) are released from the film over a long period of time. Just like the aforementioned gas in air bubbles, the outgas also finally reaches the light emitting element 24 after a long period of time and deteriorates the light emitting element 24. Moreover, because the outgas also forms air bubbles in a space present in the aforementioned interface between layers, the deterioration of adhesiveness, that is, interlayer peeling becomes more serious.

If the outgas is generated from the plastic film as the sealing substrate, the interlayer peeling and the deterioration of the light emitting element 24 due to moisture or the like are accelerated.

In contrast, the organic EL laminate 10 as an embodiment of the present invention has, as the sealing substrate, the organic layer/inorganic layer laminated structure having the inorganic film 34 and the organic film 32 as an underlayer, and uses the gas barrier film 14 which has the inorganic film 34 as a surface layer thereof.

Furthermore, the passivation film 26 and the inorganic film 34 are formed of the same material, and in a state in which the passivation film 26 and the inorganic film 34 face each other, the organic EL device 12 and the gas barrier film 14 adhere to each other by the adhesive 16.

Therefore, according to the organic EL laminate 10, as in the case of using a plastic film as a sealing substrate, the organic EL laminate can be further lightened and thinned down compared to the organic EL laminate of the related art using a glass plate or the like as a sealing substrate.

Being formed of the same material, the passivation film 26 and the inorganic film 34 can adhere to the adhesive 16 with the same force (the adhesion of the passivation film 26 and the inorganic film 34 with respect to the adhesive is the same). Consequently, it is possible to reduce a difference in stress between both the films by making the films have the same adhesion. The passivation film 26 and the gas barrier film 14 can adhere to each other with a high adhesion by using the adhesive 16 optimal for both the films. As a result, it is possible to more effectively prevent the occurrence of interlayer peeling between the passivation film 26 and the adhesive 16 and between the adhesive 16 and the inorganic film 34.

In addition, the inorganic film 34 that exhibits gas barrier properties becomes the surface layer of the gas barrier film 14, and in this state, the passivation film 26 and the inorganic film 34 are caused to face each other and adhere to each other. Therefore, even when the outgas is released from the support 30, by the inorganic film 34, the outgas is blocked and prevented from reaching the adhesive 16 or the passivation film 26. Consequently, according to the organic EL laminate 10, the deterioration of the light emitting element 24 or the interlayer peeling caused by the outgas from the support 30 can be prevented.

As shown in FIG. 1, the surface of the passivation film 26 has irregularities resulting from the light emitting element 24. Furthermore, because the inorganic film 34 formed of silicon nitride or the like is hard and brittle, if the inorganic film 34 is directly pressed against other members, damages such as cracks, fissures, and the like easily occur.

If the inorganic film 34 is damaged, moisture or the like passes through the inorganic film 34, and thus the performance of the gas barrier film 14 deteriorates. Therefore, generally, considering the damage of the inorganic film 34, it is disadvantageous to attach the organic EL device 12 to the gas barrier film 14 by bringing the inorganic film 34 into direct contact with the adhesive 16 (by bringing the inorganic film 34 into contact with the adhesive 16).

A gas barrier film is also known which has a protective organic film on the surface layer thereof to protect the inorganic film 34 as an uppermost layer. However, if such a gas barrier film is used, and the organic EL device 12 and the gas barrier film adhere to each other in a state in which the protective organic film is caused to face the passivation film 26, the same problem as in the aforementioned plastic film occurs.

In addition, in an organic EL device using an organic EL laminate, various functional layers such as a polarizing plate and 1/λ plate are formed on the organic EL laminate. If the support 30 is caused to face the passivation film 26, and the gas barrier film 14 and the organic EL device 12 adhere to each other in this state so as to cause the functional layers to function as a protective film of the inorganic film 34, the same problem as in the aforementioned plastic film occurs.

In contrast, in the organic EL laminate 10, the gas barrier film 14 has the organic film 32 as an underlayer of the inorganic film 34. Therefore, when the organic EL device 12 and the gas barrier film 14 are pressed together so as to adhere to each other, the organic film 32 protects the inorganic film 34 by functioning as a cushion for the inorganic film 34, and thus damage of the inorganic film 34 can be prevented.

Because the gas barrier film 14 has the organic film 32 as an underlayer, an appropriate inorganic film 34 can be formed. Therefore, the gas barrier film 14 demonstrates a high degree of gas barrier performance in which the water vapor transmission rate is less than 1×10⁻⁴ [g/(m²·day)]. As a result, as described above, the passivation film 26 can be thinned down, and thus the cost can be reduced. The water vapor transmission rate of the gas barrier film 14 is more preferably equal to or less than 5×10⁻⁵ [g/(m²·day)].

When the organic EL laminate has a plurality of organic layer/inorganic layer laminated structures as in the example shown in FIG. 2A, a higher cushioning effect is exerted. Accordingly, the inorganic film 34 can be more reliably protected, and high performance thereof can be maintained. Furthermore, when the organic EL laminate has a plurality of organic layer/inorganic layer laminated structures, better gas barrier performance is obtained. Consequently, the effect of reducing the cost by thinning down the passivation film becomes stronger.

Therefore, according to the organic EL laminate 10, the use of the gas barrier film 14 as a sealing substrate results in lightening and thinning down of the laminate, and the interlayer peeling that occurs inside the organic EL laminate 10 is prevented. In addition, according to the organic EL laminate 10, the effect obtained by using the gas barrier film 14 as a sealing substrate is sufficiently exerted, and accordingly, it is possible to reduce the cost by thinning down the passivation film 26 and to more preferably prevent the deterioration of the light emitting element 24 due to moisture or the like. As a result, the organic EL laminate 10 demonstrates intended performance over a long period of time.

In the organic EL laminate 10, the thickness of the adhesive 16 (the thickness of a film formed of the adhesive 16) can be appropriately set according to the size, use, and the like of the organic EL laminate 10 such that the organic EL device 12 and the gas barrier film 14 can be reliably adhere to each other.

In the organic EL laminate 10, basically, the adhesive 16 fills the entire space between the organic EL device 12 and the gas barrier film 14.

Usually, the adhesive 16 does not have gas barrier properties. Accordingly, in the organic EL laminate 10, moisture or the like is likely to permeate the laminate from the end surface of the adhesive 16 and to deteriorate the light emitting element 24 by reaching the light emitting element 24. If the adhesive 16 is too thick, the problem occurs in that ductility (flexibility) of the gas barrier film 14 deteriorates, or strong curls are formed.

Considering the aforementioned points, it is advantageous for the adhesive 16 to have a minimum thickness that is necessary for making the irregularities on the surface of the passivation film 26 embedded in the adhesive 16 (for covering the irregularities such that they become smoothened) and is necessary for enabling the organic EL device 12 and the gas barrier film 14 to reliably adhere to each other.

According to the examination performed by the present inventor, the thickness of the adhesive 16 preferably exceeds 1 μm (greater than 1 μm).

The surface of the passivation film 26 has irregularities resulting from the light emitting element 24, and the inorganic film 34 formed of silicon nitride or the like is hard and brittle. Therefore, considering damage of the inorganic film 34 such as cracks, it is disadvantageous to bring the inorganic film 34 into direct contact with the adhesive 16 such that the organic EL device 12 adheres to the gas barrier film 14.

In contrast, the thickness of the adhesive 16 may exceed 1 μm. When the organic EL device 12 and the gas barrier film 14 are pressed together so as to adhere to each other, or when the organic EL laminate 10 receives external impact, it is possible to make this adhesive 16 effectively function as a cushion for preventing damage of the inorganic film 34. Consequently, due to the synergistic effect of the function of the adhesive 16 as a cushion and the function of the organic film 32 as a cushion, damage of the inorganic film 34 can be more reliably prevented.

Considering permeation of moisture or the like from the end surface of the adhesive 16, ductility or curling of the gas barrier film 14, and the like, the thickness of the adhesive 16 is preferably equal to or less than 100 μm.

A thickness of the adhesive 16 is more preferably 2 μm to 50 μm, because damage of the inorganic film 34 can be prevented by a more preferable cushioning effect, and permeation of moisture or the like from the end surface can be prevented.

In view of lightening and thinning down the organic EL laminate 10, the total thickness of the support 30 and the adhesive 16 is preferably smaller than 300 μm which is a thickness of thin glass.

The thickness of the adhesive 16 refers to a thickness of the adhesive 16 of the thinnest portion in a position in which the light emitting element 24 is formed.

As the adhesive 16, an adhesive, which can attach the passivation film 26 to the inorganic film 34 with a sufficient adhesion, may be appropriately selected according to the material forming the passivation film 26 and the inorganic film 34. Examples of the adhesive 16 include an epoxy-based adhesive and an acryl-based adhesive.

When the organic EL laminate 10 is a top emission type, it is preferable for the adhesive 16 to have a high light transmittance. Furthermore, it is preferable for the adhesive 16 not to release outgas (or to release an extremely small amount of outgas).

If necessary, a rubber-based material such as polyisobutylene, a cycloolefin copolymer, or the like may be added to the adhesive 16 so as to improve ductility. As the cycloolefin copolymer to be added, commercially available products such as TOPAS manufactured by Polyplastics Co., Ltd. and APEL manufactured by Mitsui Chemicals, Inc. may be used.

The adhesive 16 preferably contains a silane coupling agent.

Either or both of an —O group and a —OH group are preferably introduced into the surface of each of the passivation film 26 and the inorganic film 34 that adhere to each other by the adhesive 16.

If either or both of an —O group and a —OH group are introduced into the surface as described above, the adhesiveness between the adhesive 16 and the passivation film 26 as well as the inorganic film 34 can be further improved.

The silane coupling agent is a compound in which a hydrolyzable group such as an alkoxy group and an organic functional group such as an amino group that is expected to react or interact with an organic substance are bonded to silicon.

The hydrolyzable group in the silane coupling agent becomes a —OH group through hydrolysis, dehydrocondensation occurs between the —OH group and a —OH group on the surface of an inorganic compound, and as a result, a strong covalent bond is formed between the silane coupling agent and the surface of the inorganic compound. Furthermore, the organic functional group in the silane coupling agent is copolymerized with an organic compound, and thus a strong bond is formed between the silane coupling agent and the organic compound. In this way, the silane coupling agent improves the adhesiveness between an organic substance and an inorganic substance.

Through examination, the present inventor found that when each of the passivation film 26 and the inorganic film 34 is a silicon compound, in which an —O group, preferably, a —OH group may be introduced into the surface thereof so as to create a state similar to “SiOH”, the hydrolysis reaction and dehydrocondensation of the silane coupling agent contained in the adhesive 16 would preferably occur.

If the —OH group or the like is introduced into the surface of each of the passivation film 26 and the inorganic film 34, the —OH group or the like is released from the surface of each of the passivation film 26 and the inorganic film 34. Due to the released —OH group or the like, the hydrolysis reaction of the silane coupling agent occurs, and the silicon compound and the silane coupling agent are bonded to each other through a covalent bond formed by the dehydrocondensation. As a result, the adhesiveness between the adhesive 16 and the passivation film 26 as well as the inorganic film 34 is further improved.

Generally, when the silane coupling agent is used, the pH is adjusted by adding a pH regulator (an acid or an alkali) to the adhesive. However, if the pH regulator is added to the adhesive containing the silane coupling agent, a problem occurs in that viscosity of the adhesive increases due to hydrolysis that proceeds due to the humidity of the atmosphere or water supplied from an organic solvent.

In contrast, if the adhesive 16 contains the silane coupling agent, and an —O group or a —OH group is introduced into the surface of each of the passivation film 26 formed of a silicon compound and the inorganic film 34, even though the pH is not regulated by adding the pH regulator, a strong adhesion is obtained. That is, according to such a constitution, it is possible not to add the pH regulator, which may cause a problem, to the adhesive 16.

Basically, the organic EL device 12 and the gas barrier film 14 may adhere to each other by the adhesive 16 through the same method as used for attaching a sealing substrate in a known organic EL laminate.

Either or both of the surface of the inorganic film 34 of the gas barrier film 14 and the surface of the passivation film 26 of the organic EL device 12 are coated with the adhesive 16. Thereafter, in a state in which the inorganic film 34 and the passivation film 26 are made to face each other, the organic EL device 12 and the gas barrier film 14 are laminated on each other. If necessary, the organic EL device 12 and the gas barrier film 14 are pressed together and subjected to heating, ultraviolet irradiation, and the like so as to cure the adhesive 16, thereby attaching the organic EL device 12 to the gas barrier film 14.

Hitherto, the organic EL laminate 10 has been specifically described. However, the present invention is not limited to the above examples, and within a scope that does not depart from the gist of the present invention, the present invention may be improved or modified in various ways.

### EXAMPLES

Hereinafter, the present invention will be more specifically described based on specific examples of the present invention.

### Example 1-1

A 20 mm×20 mm glass plate having a thickness of 500 μm was prepared as the element substrate 20.

The periphery (2 mm) of the element substrate 20 was masked with ceramic, and the element substrate 20 having undergone masking was loaded in a general vacuum vapor deposition apparatus. By vacuum vapor deposition, an electrode composed of aluminum metal having a thickness of 100 nm was formed, and then a lithium fluoride layer having a thickness of 1 nm was formed.

On the element substrate 20 on which the electrode and the lithium fluoride layer were formed, the following organic compound layers were sequentially formed by vacuum vapor deposition.

### (Light Emitting Layer-Cum-Electron Transport Layer)

Tris(8-hydroxyquinolinato)aluminum: film thickness of 60 nm

### (Second Hole Transport Layer)

N,N′-diphenyl-N,N′-dinaphthylbenzidine: film thickness of 40 nm

### (First Hole Transport Layer)

Copper phthalocyanine: film thickness of 10 nm

The element substrate 20 on which the above layers were formed was loaded in a general sputtering apparatus. By using indium tin oxide (ITO) as a target, a transparent electrode composed of a thin ITO film having a thickness of 0.2 μm was formed by means of DC magnetron sputtering, thereby forming the light emitting element 24 using an organic EL material.

Thereafter, from the element substrate 20 on which the light emitting element 24 was formed, the mask was removed.

The element substrate 20 from which the mask was removed was loaded in a general plasma CVD apparatus. The internal pressure of a chamber of the CVD apparatus was appropriately adjusted, and in this state, by means of plasma CVD (CCP-CVD), the passivation film 26 with a thickness of 1,500 nm composed of silicon nitride was formed, thereby preparing the organic EL device 12.

That is, the organic EL device 12 has a constitution in which a single light emitting element 24 was formed at the center thereof, and the passivation film 26 composed of silicon nitride covering the entire surface of the light emitting element 24 and the element substrate 20 was formed.

As raw material gases for forming the passivation film 26, silane gas (SiH₄), ammonia gas (NH₃), nitrogen gas (N₂), and hydrogen gas (H₂) were used. The silane gas was supplied in an amount of 100 sccm, the ammonia gas was supplied in an amount of 200 sccm, the nitrogen gas was supplied in an amount of 500 sccm, and the hydrogen gas was supplied in an amount of 500 sccm. The formation pressure (pressure for forming a film) was 50 Pa.

For plasma excitation, a power of 3,000 W was supplied at a frequency of 13.5 MHz. During the formation of the film, a bias power of 500 W was supplied to the side of the element substrate 20 (substrate holder) at a frequency of 400 kHz.

As the support 30, a 30,000 mm×1,000 mm COC film (F1 film manufactured by GUNZE LIMITED.) having a thickness of 100 μm was prepared. The water vapor transmission rate (WVTR) of the COC film was 2 [g/(m²·day)].

On the surface of the support 30, the organic film 32 having a thickness of 2 μm was formed by a coating method.

The coating for forming the organic film 32 was prepared by adding TMPTA (manufactured by Daicel-Cytec Company Ltd.), a surfactant (BYK 378 manufactured by BYK Japan KK), a photopolymerization initiator (Irg 184 manufactured by Ciba Specialty Chemicals Corporation), and a silane coupling agent (KBM 5103 manufactured by Shin-Etsu Silicones) to methyl ethyl ketone (MEK).

The amount of the surfactant added was 1% by mass expressed in terms of the concentration excluding MEK, the amount of the photopolymerization initiator added was 2% by mass expressed in terms of the concentration excluding MEK, and the amount of the silane coupling agent added was 10% by mass expressed in terms of the concentration excluding MEK. A solid content concentration of the coating, which was obtained by diluting the components mixed together in MEK at the aforementioned ratio, was 15% by mass.

The surface of the support 30 was coated with the coating by using a die coater. Thereafter, the coating was dried by dry air with a temperature of 80° C. The dried coating was polymerized by being irradiated with ultraviolet rays, thereby forming the organic film 32.

The support 30 on which the organic film 32 was formed was loaded in a general plasma CVD apparatus. By means of plasma CVD (CCP-CVD), the inorganic film 34 having a thickness of 50 nm composed of silicon nitride was formed, thereby preparing the gas barrier film 14. After the inorganic film 34 was formed, the gas barrier film 14 was left in the atmosphere.

As raw material gases, silane gas (SiH₄), ammonia gas (NH₃), nitrogen gas (N₂), and hydrogen gas (H₂) were used. The silane gas was supplied in an amount of 100 sccm, the ammonia gas was supplied in an amount of 200 sccm, the nitrogen gas was supplied in an amount of 500 sccm, and the hydrogen gas was supplied in an amount of 500 sccm. The formation pressure (pressure for forming a film) was 50 Pa.

For plasma excitation, a power of 3,000 W was supplied at a frequency of 13.5 MHz. During the formation of the film, a bias power of 500 W was supplied to the side of the support 30 (substrate holder) at a frequency of 400 kHz.

The coating for forming the adhesive 16 was prepared by adding two kinds of epoxy resins (JER 1001 and JER 152 manufactured by Japan Epoxy Resins Co., Ltd.) and a silane coupling agent (KBM 502 manufactured by Shin-Etsu Silicones) to MEK.

The amount of the two kinds of epoxy resins added was 48% by mass expressed in terms of the concentration excluding MEK, and the amount of the silane coupling agent added was 4% by mass expressed in terms of the concentration excluding MEK. A solid content concentration of the coating, which was obtained by diluting the components mixed together in MEK at the aforementioned ratio, was 50% by mass.

The gas barrier film 14 was cut in the form of a 20 mm×20 mm sheet just like the element substrate 20.

The surface of the inorganic film 34 of the cut gas barrier film 14 was coated with the coating, which will become the adhesive 16, by using a die coater. The coating was applied such that the thickness of the adhesive 16 became 10 μm. Subsequently, the coating was dried by being heated for 30 seconds at 100° C.

After the coating was dried, in an inert gas atmosphere, the passivation film 26 was caused to face the coating (that is, the passivation film 26 and the inorganic film 34 were caused to face each other), and in this state, the organic EL device 12 and the gas barrier film 14 were laminated on and adhered to each other.

The laminate was held in a constant-temperature bath with a temperature of 100° C. for 100 hours so as to cure the adhesive 16 (coating), thereby preparing the organic EL laminate 10 as shown in FIG. 1.

### Comparative Example 1-1

An organic EL laminate was prepared in the same manner as in Example 1, except that in the gas barrier film 14, instead of the inorganic film 34 formed of silicon nitride, an inorganic film 34 having a thickness of 50 nm composed of aluminum oxide was formed.

The inorganic film 34 composed of aluminum oxide was formed by performing reactive sputtering using aluminum as a target by using a general sputtering apparatus.

Argon gas was used as discharge gas, and oxygen gas was used as reactant gas. The argon gas was supplied in an amount of 50 sccm, and the oxygen gas was supplied in an amount of 200 sccm.

The formation pressure was 1.5×10⁻¹ Pa, and the supplied power was 2,300 W.

### Comparative Example 1-2

An organic EL laminate was prepared in the same manner as in Example 1, except that instead of the gas barrier film 14, a gas barrier film was used in which an organic film having a thickness of 2 μm was additionally formed on the inorganic film 34.

The organic film as the uppermost layer was formed in the same manner as the organic film 32 which was formed on the surface of the support 30 in Example 1.

### Example 1-2

An organic EL laminate was prepared in the same manner as in Example 1, except that the adhesive 16 did not contain a silane coupling agent.

### Comparative Example 1-3

An organic EL laminate was prepared in the same manner as in Example 1, except that the support 30 was coated with the adhesive 16 and laminated on and adhere to the passivation film 26 in a state of facing the passivation film 26 (that is, except that the support 30 (COC film) became the surface of the organic EL laminate).

### Examples 2-1 to 2-5

Organic EL laminates (Examples 2-1 to 2-5) were prepared in the same manner as in Example 1, except that the thickness of the adhesive 16 of the gas barrier film 14 was changed. Specifically, the thickness of the adhesive 16 of the gas barrier film 14 was changed to 50 μm (Example 2-1), 5 μm (Example 2-2), 2 μm (Example 2-3), 1 μm (Example 2-4), and 300 μm (Example 2-5).

### Example 3

The organic EL laminate 10 was prepared in the same manner as in Example 1, except that as the support 30 of the gas barrier film 14, a PC film (Elmec R140 manufactured by Kaneka Corporation) having a water vapor transmission rate (WVTR) of 160 [g/(m²·day)] was used, and the thickness of the adhesive 16 was changed to 50 μm.

### Example 4

The organic EL laminate 10 was prepared in the same manner as in Example 1, except that as a support of the gas barrier film 14, a PET film having a water vapor transmission rate (WVTR) of 5 [g/(m²·day)] was used.

### Example 5

The organic EL laminate 10 was prepared in the same manner as in Example 1, except that as a support of the gas barrier film 14, a TAC film having a water vapor transmission rate (WVTR) of 500 [g/(m²·day)] was used.

<Evaluation>

Each of the organic EL laminates 10 of Examples 1-1 to 3 prepared as above and each of the organic EL laminates of Comparative examples 1-1 to 1-3 were left in an environment with a temperature of 60° C. and humidity of 90% RH for 200 hours.

After being left in the aforementioned environment, each of the organic EL laminates was caused to emit light by applying a voltage of 7 V thereto by using a source measure unit of a type of SMU 2400 manufactured by Keithley Instruments Inc.

By using a microscope, the organic EL laminate was observed from the side of the support 30 of the gas barrier film 14 so as to determine whether or not a dark spot occurred.

When the occurrence of a dark spot was not observed at all (when a light emitting area was 100%), the organic EL laminate was evaluated to be “excellent”; when the occurrence of a dark spot was slightly observed (when a light emitting area was equal to or greater than 90% and less than 100%), the organic EL laminate was evaluated to be “fair”; when the occurrence of a dark spot was clearly observed (when a light emitting area was equal to or greater than 80% and less than 90%), the organic EL laminate was evaluated to be “acceptable”; and when a dark spot occupied a large area of the organic EL laminate (when a light emitting area was less than 80%), the organic EL laminate was evaluated to be “unacceptable”. When the light emitting area is equal to or greater than 80%, the organic EL laminate is acceptable even if the occurrence of a dark spot is determined.

The results are shown in the following Table 1.

TABLE 1

| | Gas barrier film | | | | | | | |
|---|---|---|---|---|---|---|---|---|
| | | | Support | WVTR of | WVTR of gas | Adhesive | | |
| | | Material of | Retardation | support | barrier film | Thickness | Coupling | |
| | Surface | support | [nm] | [g/(m² · day)] | [g/(m² · day)] | [μm] | agent | Evaluation |
| Example 1-1 | Silicon nitride | COC | 5 | 2 | 4.5 × 10⁻⁵ | 10 | Contained | Excellent |
| Comparative | Aluminum oxide | COC | 5 | 2 | 2.4 × 10⁻⁵ | 10 | Contained | Unacceptable |
| example 1-1 | | | | | | | | |
| Comparative | Organic film | COC | 5 | 2 | 3.1 × 10⁻⁴ | 10 | Contained | Unacceptable |
| example 1-2 | | | | | | | | |
| Example 1-2 | Silicon nitride | COC | 5 | 2 | 4.5 × 10⁻⁵ | 10 | Not | Acceptable |
| | | | | | | | contained | |
| Comparative | COC | COC | 5 | 2 | 2 | 10 | Contained | Unacceptable |
| example 1-3 | | | | | | | | |
| Example 2-1 | Silicon nitride | COC | 5 | 2 | 4.5 × 10⁻⁵ | 50 | Contained | Excellent |
| Example 2-2 | Silicon nitride | COC | 5 | 2 | 4.5 × 10⁻⁵ | 5 | Contained | Fair |
| Example 2-3 | Silicon nitride | COC | 5 | 2 | 4.5 × 10⁻⁵ | 2 | Contained | Fair |
| Example 2-4 | Silicon nitride | COC | 5 | 2 | 4.5 × 10⁻⁵ | 1 | Contained | Acceptable |
| Example 2-5 | Silicon nitride | COC | 5 | 2 | 4.5 × 10⁻⁵ | 300 | Contained | Acceptable |
| Example 3 | Silicon nitride | PC | 142 | 160 | 8.5 × 10⁻⁵ | 50 | Contained | Fair |
| Example 4 | Silicon nitride | PET | 400 | 5 | 5.0 × 10⁻⁵ | 10 | Contained | Fair |
| Example 5 | Silicon nitride | TAC | 10 | 500 | 9.0 × 10⁻⁵ | 10 | Contained | Acceptable |

* All of the passivation films of the organic EL device are silicon nitride films.

As is evident from Table 1, the occurrence of a dark spot was further inhibited in the organic EL laminates 10 of Examples 1-1 to 5 than in the organic EL laminates of Comparative examples 1-1 to 1-3.

In Example 1-1, in which the inorganic film 34 was the surface of the gas barrier film 14, the passivation film 26 of the organic EL device and the inorganic film 34 of the gas barrier film were formed of the same material, and the passivation film 26 and the inorganic film 34 adhered to each other by the adhesive 16 in a state of facing each other, a dark spot did not occur, and excellent light emitting performance was obtained.

Presumably, this is because the adhesiveness between the adhesive 16 and the passivation film 26 as well as the inorganic film 34 was excellent, the adhesive 16 preferably functioned as a cushioning layer of the inorganic film 34, and accordingly, deterioration of the light emitting element 24 caused by the permeation of moisture from a peeled interface or caused by the permeation of moisture resulting from the damage of the inorganic film 34 was prevented.

In contrast, in Comparative example 1-1 in which the passivation film 26 of the organic EL device and the inorganic film 34 of the gas barrier film were formed of different materials, a large number of dark spots occurred. Presumably, this is because the adhesiveness between the inorganic film 34 and the adhesive 16 was poor, interfacial peeling, formation of an air layer, and the like occurred between the inorganic film 34 and the adhesive 16, and accordingly, moisture permeated the organic EL laminate from the space between the inorganic film 34 and the adhesive 16, and the light emitting element 24 deteriorated. Furthermore, in Comparative example 1-1, fading assumed to be caused by the permeation of moisture was observed on the entire surface of the organic EL laminate.

Presumably, in Comparative example 1-2 in which the organic film was the surface of the gas barrier film, the light emitting element 24 deteriorated due to outgas generated from the organic film as the surface, and therefore a dark spot occurred.

In Example 1-2 in which the adhesive 16 did not contain a silane coupling agent, the occurrence of a dark spot was observed. Presumably, this is because the adhesiveness between the adhesive 16 and the passivation film 26 as well as the inorganic film 34 was poorer in Example 1-2 than in Example 1-1, peeling, the formation of an air layer, or the like occurred between the adhesive 16 and the passivation film 26 as well as the inorganic film 34, and accordingly, moisture permeated the organic EL laminate from the space between the adhesive 16 and the passivation film 26 as well as the inorganic film 34, and the light emitting element 24 deteriorated. In addition, in Comparative example 1-3, in which the support that was not the inorganic film 34 but the COC film was laminated on the passivation film 26 in a state of facing the passivation film 26, a large number of dark spots occurred. Presumably, this is because the adhesiveness between the adhesive 16 and the support (gas barrier film) was poor, the interfacial peeling, the formation of an air layer, or the like occurred between the adhesive 16 and the support, and accordingly, moisture permeated the organic EL laminate from the space between the adhesive 16 and the support, and the light emitting element 24 deteriorated. Moreover, in Comparative example 1-3, fading assumed to be caused by the permeation of moisture was observed on the entire surface of the organic EL laminate.

In Example 2-1 in which the adhesive 16 had a thickness of 50 μm, just like Example 1-1, due to the excellent adhesiveness or cushioning effect, a dark spot did not occur, and excellent light emitting performance was obtained.

In Example 2-2 in which the adhesive 16 had a thickness of 5 μm and in Example 2-3 in which the adhesive 16 had a thickness of 2 μm, the occurrence of a dark spot was slightly observed. Presumably, because the thickness of the adhesive 16 was smaller in Examples 2-2 and 2-3 than in Example 1-1, the inorganic film 34-protecting effect exerted by the adhesive 16 functioning as a cushion was slightly diminished. It is considered that, as a result, in Examples 2-2 and 2-3, the inorganic film 34 of the gas barrier film 14 was more easily damaged than in Example 1-1 due to the irregularities on the surface (passivation film 26) of the organic EL device 12 that result from the light emitting element 24, and therefore, moisture permeated the organic EL laminate from the inorganic film 34, and the portion in which the light emitting element 24 deteriorated occurred.

In Example 2-4 in which the adhesive 16 had a thickness of 1 μm, the occurrence of a dark spot was observed. Presumably, in Example 2-4, the inorganic film 34-protecting effect exerted by the adhesive 16 functioning as a cushion was further diminished than in Example 1-1. It is considered that, as a result, in Examples 2-4, the inorganic film 34 of the gas barrier film 14 was more easily damaged than in Example 1-1 due to the irregularities on the surface (passivation film 26) of the organic EL device 12 that result from the light emitting element 24, and therefore, moisture permeated the organic EL laminate from the inorganic film 34, and the light emitting element 24 deteriorated. In Example 2-5 in which the adhesive 16 had a thickness of 300 μm, the occurrence of a dark spot was observed. Presumably, this is because the adhesive 16 was too thick in Example 2-5 compared to Example 1-1, and accordingly, a large amount of moisture permeated the organic EL laminate from the end of the adhesive 16, and the light emitting element 24 deteriorated.

In Example 3 in which the support 30 of the gas barrier film 14 had a water vapor transmission rate of 160 [g/(m²·day)], the occurrence of a dark spot was slightly observed. Presumably, this is because the amount of moisture passing through the support 30 was larger in Example 3 than in Example 1-1. It is considered that, as a result, the load of the gas barrier film 14 is greater in Example 3 than in Example 1-1, and accordingly, moisture permeated the organic EL laminate, and the portion in which the light emitting element 24 deteriorated occurred.

In Example 4, the occurrence of a dark spot was slightly observed. In Examples 1-1 to 3 and 5, and Comparative examples 1-1 to 2-5, brightness unevenness was not observed. In contrast, in Example 4, brightness unevenness was slightly observed.

In Example 5, the occurrence of a dark spot was observed. Presumably, the water vapor transmission rate was higher in Example 5 than in Example 1-1, and accordingly, the amount of moisture passing through the support 30 was greater in Example 5. It is considered that, as a result, moisture more easily permeated the organic EL laminate in Example 5 than in Example 1-1, and thus a portion in which the light emitting element 24 deteriorated occurred.

The aforementioned results clearly show the effects of the present invention.

The present invention can be preferably used in organic EL displays, organic EL illumination devices, and the like.

What is claimed is:

1. An organic EL laminate comprising:
an organic EL device having a light emitting element using an organic EL material and a passivation film covering the light emitting element; and
a gas barrier film sealing the organic EL device,
wherein the organic EL device and the gas barrier film adhere to each other by an adhesive,
the gas barrier film has a support and one or more combinations composed of an inorganic film and an organic film that is an underlayer of the inorganic film, the combinations being on the support,
a surface layer of the gas barrier film is an inorganic film,
the passivation film and the surface layer of the gas barrier film are formed of the same material, and
the passivation film and the surface layer of the gas barrier film face each other.

2. The organic EL laminate according to claim 1,
wherein a thickness of the adhesive is greater than 1 μm and equal to or less than 100 μm.

3. The organic EL laminate according to claim 1,
wherein the adhesive contains a silane coupling agent,
each of the passivation film and the surface layer of the gas barrier film is a film of a silicon compound, and
at least either an —O group or a —OH group is introduced into a surface of the film of the silicon compound.

4. The organic EL laminate according to claim 2,
wherein the adhesive contains a silane coupling agent,
each of the passivation film and the surface layer of the gas barrier film is a film of a silicon compound, and
at least either an —O group or a —OH group is introduced into a surface of the film of the silicon compound.

5. The organic EL laminate according to claim 1,
wherein each of the passivation film and the surface layer of the gas barrier film is a film of silicon nitride.

6. The organic EL laminate according to claim 1,
wherein a value of retardation of the support is equal to or less than 300 nm.

7. The organic EL laminate according to claim 1,
wherein a water vapor transmission rate of the support is equal to or less than 300 [g/(m²·day)].

8. The organic EL laminate according to claim 1,
wherein a water vapor transmission rate of the gas barrier film is less than 1×10⁻⁴ [g/(m²·day)].

9. The organic EL laminate according to claim 1,
wherein a thickness of the passivation film is equal to or less than 5 μm.

10. The organic EL laminate according to claim 1,
wherein a thickness of the organic film is 0.5 μm to 5 μm.

11. The organic EL laminate according to claim 1,
wherein the organic EL device is a top emission type.

12. The organic EL laminate according to claim 1,
wherein a plurality of the inorganic films is provided, and
all of the inorganic films are formed of the same material.
